(19) United States
(12) Patent Application Publication
(10) Pub. No.: US 2025/0001495 A1
(43) Pub. Date: Jan. 2, 2025

(54) SELF-SUPPORTING FILM, LAMINATED SHEET, AND METHOD FOR MANUFACTURING SELF-SUPPORTING FILM

(71) Applicant: WASEDA UNIVERSITY, Tokyo (JP)

(72) Inventors: Suguru NODA, Tokyo (JP); Sebun MUNAKATA, Tokyo (JP)

(21) Appl. No.: 18/709,144

(22) PCT Filed: Nov. 10, 2022
(86) PCT No.: PCT/JP2022/041894

§ 371 Date: May 10, 2024

(30) Foreign Application Priority Data
Nov. 12, 2021 (JP) 2021-184864

(51) Int. Cl. B22F 3/11; B22F 1/052

(52) U.S. Cl. CPC B22F 3/1103; B22F 1/052; B22F 2301/255

(57) ABSTRACT

Provided are a self-supporting film, a stacked sheet, and a method for producing a self-supporting film, the self-supporting film exhibiting low electrical resistance, low thermal resistance, and high mechanical strength, being excellent in heat resistance and flexibility, and capable of being mass-produced at low cost. A self-supporting film 1 has a porous structure consisting of aggregates 3 of metal particles 2 and voids 4. A method for producing the self-supporting film 1 includes: evaporating a metal in an inert gas of 10 Torr or more and 300 Torr or less; generating the metal particles 2 made of the metal; depositing the metal particles 2 on a substrate to form, on the substrate, a self-supporting film precursor having a porous structure consisting of the aggregates 3 of the metal particles 2 and the voids 4; and peeling the self-supporting film precursor from the substrate. A stacked sheet includes the self-supporting film 1 having a porous structure consisting of the aggregates 3 of the metal particles 2 and the voids 4, and a carrier substrate.

### TECHNICAL FIELD

The present invention relates to a self-supporting film, a stacked sheet, and a method for producing a self-supporting film.

### BACKGROUND ART

Since performance of an electronic device is often controlled by a solid-solid bonding interface between the electronic device and a circuit board, performance of a thermal interface material (TIM) for electrically, thermally, and mechanically bonding the solid-solid interface is important. In the related art, as a TIM, a solder using an alloy having a low melting point and an Ag paste in which silver particles (Ag particles) having excellent electrical conductivity and oxidation resistance are made into slurry with an organic polymer and a solvent have been widely used. However, the heat resistance of the solder is necessarily lower than the melting point. The Ag paste has high electrical resistance and low heat resistance because the organic polymer inhibits bonding between the Ag particles.

The present inventors have proposed a structure in which an Ag foil is used as a support and Ag aerogel films are formed on both surfaces of the Ag foil (for example, Non-Patent Literatures 1 and 2).

### CITATION LIST

### Non-Patent Literature

Non-Patent Literature 1: Munakata, et al., “Creation of Ag aerogel film by gas-evaporation and particle-deposition method and application of thermal interface material”, Society for Chemical Engineers, Japan, Collection of Summaries of 84th Council (2019), PC253
Non-Patent Literature 2: Munakata, et al., APCChE2019, PD279, Sep. 24, 2019.

### SUMMARY OF INVENTION

### Technical Problem

The structures disclosed in Non-Patent Literatures 1 and 2 have low electrical resistance, low thermal resistance, high mechanical strength, and heat resistance, but the flexibility is impaired due to the hard Ag foil, and the interface traceability is limited as the TIM application. The Ag foil has high density and requires a large amount of Ag, and thus is unsuitable for mass production due to a problem of production cost.

Therefore, an object of the present invention is to provide a self-supporting film, a stacked sheet, and a method for producing a self-supporting film, the self-supporting film exhibiting low electrical resistance, low thermal resistance, and high mechanical strength, being excellent in heat resistance and flexibility, and capable of being mass-produced at low cost.

### Solution to Problem

A self-supporting film according to the present invention has a porous structure consisting of aggregates of metal particles and voids.

A stacked sheet according to the present invention includes the self-supporting film and a carrier substrate.

A method for producing a self-supporting film according to the present invention includes: evaporating a metal in an inert gas of 10 Torr or more and 300 Torr or less; generating metal particles made of the metal; depositing the metal particles on a substrate to form, on the substrate, a self-supporting film precursor having a porous structure consisting of aggregates of the metal particles and voids; and peeling the self-supporting film precursor from the substrate.

### Advantageous Effects of Invention

According to the present invention, it is possible to provide a self-supporting film, a stacked sheet, and a method for producing a self-supporting film, the self-supporting film exhibiting low electrical resistance, low thermal resistance, and high mechanical strength, being excellent in heat resistance and flexibility, and capable of being mass-produced at low cost.

### BRIEF DESCRIPTION OF DRAWINGS

(a) of FIG. 1 is a schematic diagram illustrating a self-supporting film to which the present invention is embodied, (b) of FIG. 1 is a photograph taken by a digital camera showing a state where the self-supporting film to which the present invention is embodied is lifted by tweezers, and (c) of FIG. 1 is an SEM image showing a surface of the self-supporting film to which the present invention is embodied.

FIG. 2 is a diagram illustrating a method of using a self-supporting film for an interfacial bonding material.

FIG. 3 is a schematic diagram illustrating a main part of a self-supporting film production apparatus.

FIG. 4 is a diagram illustrating a method for producing the self-supporting film.

FIG. 5 is a diagram showing a relation between a pressure of an inert gas and characteristics of the self-supporting film.

(a) of FIG. 6 is a graph showing a film thickness and a packing ratio before and after pressing with respect to the pressure of the inert gas, and (b) of FIG. 6 is a graph showing a packing ratio after pressing and a film thickness deformation rate with respect to a packing ratio before pressing.

FIG. 7 is a graph showing thermal resistance with respect to a packing ratio before pressing.

FIG. 8 is a graph showing the thermal resistance in an example and comparative examples.

(a) of FIG. 9 is a graph showing a change in thermal resistance with respect to a temperature during pressing, (b) of FIG. 9 is an SEM image showing a cross section of the self-supporting film at a point indicated by P1 in (a) of FIG. 9, and (c) of FIG. 9 is an SEM image showing a cross section of the self-supporting film at a point indicated by P2 in (a) of FIG. 9.

FIG. 10 is a diagram showing test results of the heat resistance in an example and a comparative example.

FIG. 11 is a graph showing electrical resistance in examples and comparative examples.

FIG. 12 is a graph showing test results of mechanical strength.

FIG. 13 is a schematic diagram schematically illustrating an example of a stacked sheet manufacturing apparatus.

### DESCRIPTION OF EMBODIMENTS

Hereinafter, exemplary embodiments the present invention will be described in detail with reference to the drawings. In the following embodiments, the same or similar components are denoted by the same reference numerals throughout the drawings.

### 1. OVERALL CONFIGURATION

In (a) of FIG. 1, a self-supporting film 1 has a porous structure consisting of aggregates 3 of metal particles 2 and voids 4. In the present application, the “porous structure” means a structure in which aggregates of particles are linked in a rosary shape to form a three-dimensional network. The “porous structure” in the present application, particularly with respect to a gel formed of a continuous phase of solid particles connected to one another and a dispersed phase of a liquid, includes an “aerogel structure” formed of air and a continuous phase of solid particles connected to one another. (b) of FIG. 1 is a photograph showing a state where the self-supporting film 1 is lifted by tweezers. It is understood that the self-supporting film 1 does not crack even when being lifted by tweezers, and is self-supporting. (c) of FIG. 1 is a scanning electron microscope (SEM) image of the self-supporting film 1.

A volume average particle diameter of the metal particles 2 is 0.1 μm or more and 3 μm or less. The volume average particle diameter of the metal particles 2 is preferably 0.5 μm or more and 2 μm or less, and more preferably 0.6 μm or more and 1.5 μm or less. A method for calculating the volume average particle diameter of the metal particles 2 is not particularly limited. For example, the self-supporting film 1 may be observed using the SEM, and the particle diameter of the plurality of metal particles 2 may be measured from an obtained SEM image, and then the volume average particle diameter may be calculated based on measured particle diameter distribution.

The metal particles 2 are made of silver (Ag). A mass of silver per unit area (also referred to as area loading) in the self-supporting film 1 is 1 mg/cm² or more and 50 mg/cm² or less. The mass of silver per unit area of the self-supporting film 1 is preferably 3 mg/cm² or more and 30 mg/cm² or less, and more preferably 5 mg/cm² or more and 20 mg/cm² or less. The metal particles 2 are preferably connected to one another to form a continuous phase.

The voids 4 are formed among the plurality of metal particles 2 constituting the aggregates 3. The voids 4 contain gas. The gas is air or an inert gas. Examples of the inert gas include argon gas and nitrogen gas. The voids 4 are preferably connected to one another to form a continuous phase.

A porosity of the self-supporting film 1 is 50 vol % or more and 99 vol % or less. The porosity is a ratio of a volume of the voids 4 to a total volume of the self-supporting film 1, and is a volume ratio of the gas in the self-supporting film 1. The porosity is preferably 80 vol % or more and 95 vol % or less, and more preferably 85 vol % or more and 90 vol % or less.

The self-supporting film 1 consists of the aggregates 3 of the metal particles 2 and the voids 4, and does not include anything other than the metal particles 2 and the voids 4. The self-supporting film 1 does not include a metal foil. When the metal particles 2 are made of silver, the self-supporting film 1 includes only of silver particles and voids. Here, a mass of silver per unit area of the Ag foil is 31.5 mg/cm² when the Ag foil has a thickness of 30 μm. The self-supporting film 1 does not include an Ag foil, thereby implementing a small mass of silver per unit area, which is 1 mg/cm² or more and 30 mg/cm² or less.

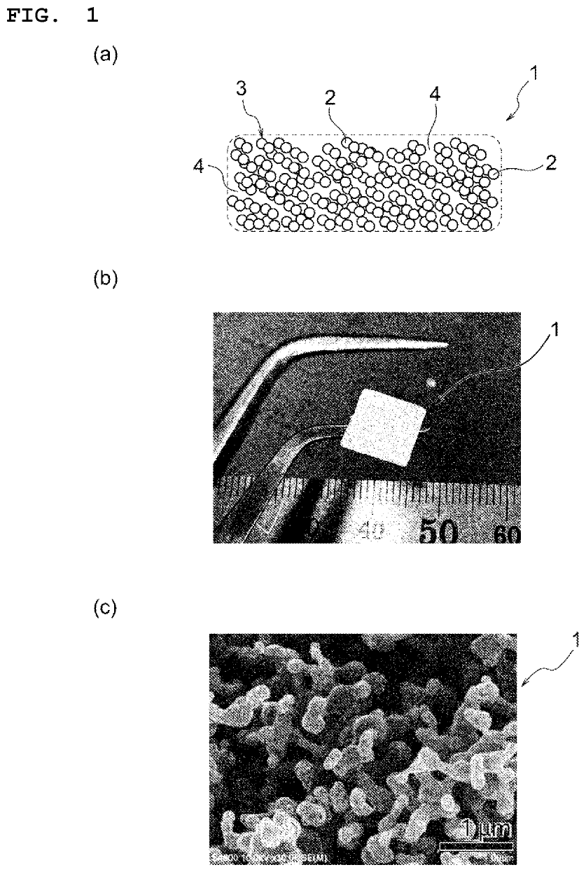

As illustrated in FIG. 2, the self-supporting film 1 is disposed between two solids 6 and 7 facing each other, pressed, and used to connect the solids 6 and 7. The pressing is performed at room temperature or while heating. The self-supporting film 1 has a high porosity and does not include a metal foil, and thus has high flexibility and high traceability on the interface. Although even a solid having a flat surface has micro roughness on the surface, the self-supporting film 1 is deformed in accordance with the roughness on the surface of each of the solids 6 and 7 when pressed, and adheres to the surfaces of the solids 6 and 7. The self-supporting film 1 is used as a self-supporting film for an interfacial bonding material for bonding the solids 6 and 7 to each other.

Since the self-supporting film 1 consists of the metal particles 2 and the voids 4 and does not contain an organic polymer, the voids 4 are crushed and reduced by pressing, a gap between the solids 6 and 7 are filled with the plurality of metal particles 2, the metal particles 2 are in direct contact with one another, and the thermal resistance and the electrical resistance can be reduced. Since the self-supporting film 1 does not contain an organic polymer which is thermally unstable, the thermal stability is excellent, and the heat resistance of the bonding interface is improved.

In the self-supporting film 1, by pressing, the plurality of metal particles 2 are bonded to one another by sintering. Sintering means bonding the metal particles 2 in a solid state without melting. Since the self-supporting film 1 has a nanostructure including the metal particles 2 having a clean surface and a volume average particle diameter of 0.1 μm or more and 3 μm or less, even when being pressed at a temperature of 200° C. or lower, which is much lower than 962° C., which is the melting point of silver, silver particles are bonded by the sintering, and the particle diameter increases to become bulky. Since a dense bulky bonding portion is formed by the plurality of metal particles 2, the thermal resistance and the electrical resistance of the bonding interface are reduced, and the mechanical strength and the heat resistance are improved up to a bulk equivalent. Since the void 4 before pressing remains even in the case of a bulky structure, the bonding interface has excellent resistance to thermal stress and mechanical stress. Sintering also occurs due to the nanostructure of the self-supporting film 1 by pressing at room temperature.

When the solid 6 illustrated in FIG. 2 is a heating element such as an integrated circuit (IC) chip and the solid 7 is a heat radiator such as a heat sink, the self-supporting film 1 is used as a self-supporting film for a thermal interface material, and heat can be efficiently transferred from the solid 6 as a heating element to the solid 7 as a heat radiator.

### 2. PRODUCTION METHOD

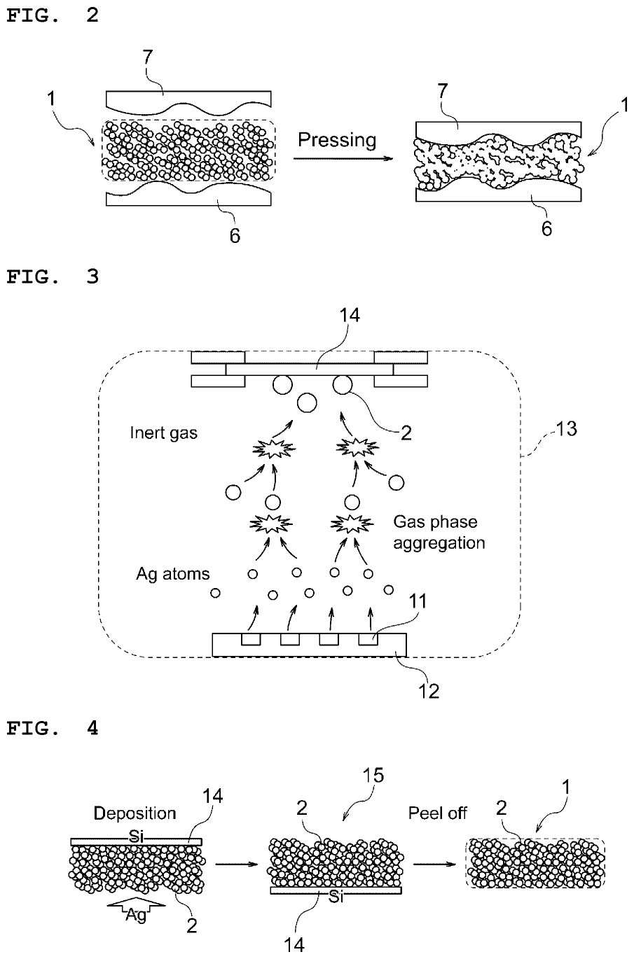

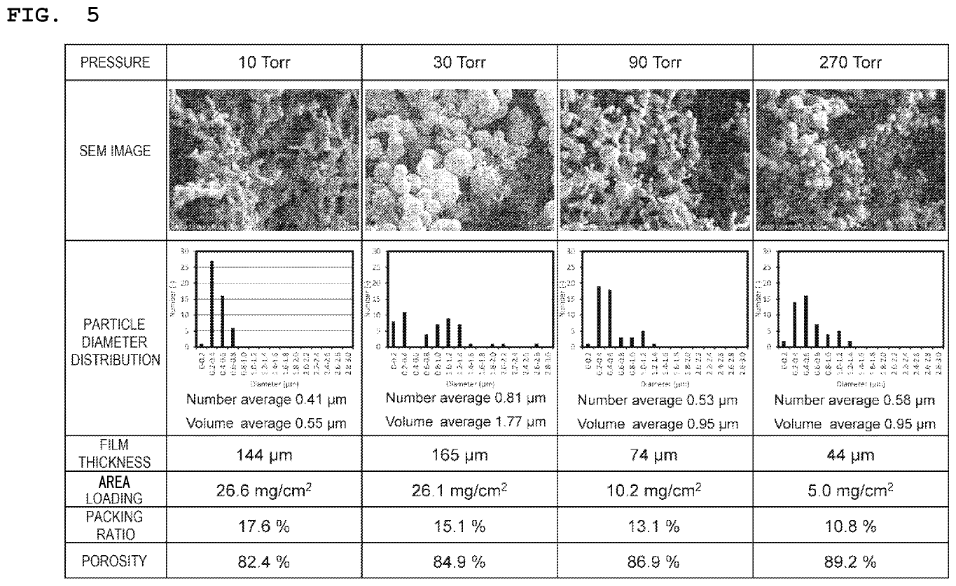

A method for producing the self-supporting film 1 will be described below with reference to FIGS. 3 and 4. The self-supporting film 1 can be produced by a gas-evaporation and particle-deposition method.

FIG. 3 is a schematic diagram illustrating a main part of a self-supporting film manufacturing apparatus. In this example, a method for producing the self-supporting film 1 using the gas-evaporation and particle-deposition method will be specifically described.

First, as illustrated in FIG. 3, a metal 11 is evaporated in an inert gas (for example, argon gas) of 10 Torr or more and 300 Torr or less to generate the metal particles 2 made of the metal 11, and the metal particles 2 are deposited on a substrate 14 to form a film having a porous structure (aerogel structure). Specifically, the metal 11 (Ag) serving as a vapor deposition source is disposed on a boat 12 for vapor deposition, the boat 12 is disposed in a chamber 13, the inside of the chamber 13 is evacuated by a vacuum generating device not illustrated, and then the inert gas is flowed into the chamber 13 to adjust a pressure in the chamber 13 to 10 Torr or more and 300 Torr or less. Although a temperature of the substrate 14 may be room temperature, the temperature of the substrate 14 may be adjusted to, for example, 0° C. to 300° C. by a heater and a cooling mechanism not illustrated. Then, the metal 11 disposed on the boat 12 is evaporated by raising the temperature of the boat 12 by electric heating using a power source not illustrated. For example, the evaporation of Ag is completed by raising the temperature of the boat 12 to 2,000° C. or higher in 5 seconds and maintaining the temperature for 115 seconds.

Atoms (Ag atoms) of the evaporated metal 11 (Ag) are cooled by the inert gas, hit one another, and coalesce to form Ag nanoparticles, the formed Ag nanoparticles hit one another in the inert gas and coalesce to generate the metal particles 2 (also referred to as Ag particles), and the metal particles 2 are deposited on the substrate 14. As the pressure of the inert gas increases, a mean free path of the Ag atoms and the Ag nanoparticles becomes shorter, the Ag atoms hit one another, the Ag nanoparticles hit one another, and the Ag atoms and the Ag nanoparticles hit one another, so that the metal particles 2 made of Ag become larger. A size of the metal particles 2 can be controlled by adjusting the pressure of the inert gas flowing into the chamber 13. As illustrated in FIG. 4, the generated metal particles 2 are deposited on the substrate 14 to form a self-supporting film precursor 15 having a porous structure consisting of the aggregates 3 of the metal particles 2 and the voids 4. The number of times the metal particles 2 are deposited on the substrate 14 is once in the example illustrated in FIG. 4, but is not limited thereto, and may be plural times.

By disposing a mask having a predetermined opening on the substrate 14, the self-supporting film precursor 15 can be deposited with a size of the predetermined opening. The size of the self-supporting film precursor 15 is any size, but can be 1 cm×1 cm, for example, by using a mask provided with a square opening having a length on one side of 1 cm. By changing the shape of the mask and the size of the opening, an area of the self-supporting film precursor 15 (area of plane orthogonal to film thickness direction) can be, for example, 100 cm² or less.

Next, the self-supporting film precursor 15 is peeled off from the substrate 14. The film peeled off from the substrate 14 is the self-supporting film 1. A reason why a self-supporting film can be fabricated only with Ag particles without using a binder or the like is that, in the manufacturing process, Ag particles having a particle diameter of several tens to several hundreds of nanometers are deposited on the substrate 14, and the Ag particles are sintered and bonded to one another in a plane-perpendicular direction and an in-plane direction by heat radiation to form a three-dimensional network. In the example illustrated in FIG. 4, the self-supporting film precursor 15 is peeled off from the substrate 14 after the substrate 14 is turned upside down. The substrate 14 may be formed of a material having poor wettability with the metal 11, but may be any material having a surface formed of a material having poor wettability with the metal 11. The surface of the substrate 14 is preferably a smooth surface. When the metal 11 is Ag, for example, an Si substrate may be used as the substrate 14. It is desirable that the Si substrate has a natural oxide film or a thermal oxide film on a surface thereof.

The peeling can be performed by, for example, a method of peeling with tweezers while feeding air with a blower, a method of transferring to a carrier substrate, and a method of pressing the self-supporting film precursor 15 in a direction parallel to the surface of the substrate 14 by bringing one side of a flat plate into contact with one side of the self-supporting film precursor 15. By the peeling, the self-supporting film 1 having the same size as the self-supporting film precursor 15 is obtained.

### 3. OPERATION AND EFFECT

The self-supporting film 1 includes only the metal particles 2 and the voids 4, has a high porosity, and does not include a metal foil. When the self-supporting film 1 is disposed between the solids and pressed, the voids 4 are crushed and compressed, and the self-supporting film 1 flexibly traces the shape of the interface between the solids. The self-supporting film 1 does not include a metal foil, thereby being excellent in flexibility and flexibly tracing the shape of the interface between the solids. The manufacturing cost is reduced as compared with the case where a metal foil is used.

The self-supporting film 1 includes only the metal particles 2 and the voids 4. Since the self-supporting film 1 does not contain an organic polymer, the voids 4 are crushed and reduced by pressing, a gap between the solids 6 and 7 are filled with the plurality of metal particles 2, the metal particles 2 are in direct contact with one another, and the thermal resistance and the electrical resistance can be reduced. Since the self-supporting film 1 does not contain an organic polymer which is thermally unstable, the thermal stability is excellent, and the heat resistance of the bonding interface is improved.

The self-supporting film 1 includes only the voids 4 and the metal particles 2 having a clean surface and a volume average particle diameter of 0.1 μm or more and 3 μm or less. Even when the self-supporting film 1 is pressed at a temperature lower than the melting point of the metal constituting the metal particles 2, the plurality of metal particles 2 are bonded to one another by sintering. The plurality of metal particles 2 are bonded to one another by sintering, the particle diameter is increased, and a dense bulky bonding portion is formed. Accordingly, characteristics of a bulk are exhibited, the thermal resistance and the electrical resistance of the bonding interface are reduced, and the mechanical strength and the heat resistance are improved. Even in the case of a bulky structure, the voids 4 before pressing remain partially, and thus the bonding interface is also excellent in resistance to thermal stress and mechanical stress. The bonding of the metal particles 2 by the sintering also occurs by pressing at room temperature.

As described above, the self-supporting film 1 has a porous structure consisting of the aggregates 3 of the metal particles 2 and the voids 4, thereby exhibiting low electrical resistance, low thermal resistance, and high mechanical strength, being excellent in heat resistance and flexibility, and capable of being mass-produced at low cost.

When the volume average particle diameter of the metal particles 2 is less than 0.1 μm, sintering proceeds between the metal particles 2 at room temperature with the lapse of time, the flexibility is impaired, and the self-supporting film 1 does not trace the shape of the interface. Therefore, characteristics of low electrical resistance, low thermal resistance, and high mechanical strength are not exhibited. When the volume average particle diameter of the metal particles 2 exceeds 3 μm, a surface area of the metal particles 2 is reduced and a contact area between the metal particles 2 is reduced. Therefore, it is difficult to form a self-supporting film state. When the volume average particle diameter of the metal particles 2 is 0.1 μm or more and 3 μm or less, the self-supporting film 1 exhibits low electrical resistance, low thermal resistance, and high mechanical strength, is excellent in heat resistance and flexibility, and can be mass-produced at low cost.

When the porosity of the self-supporting film 1 is less than 50 vol %, deformation tracing the surface of the solid becomes difficult. When the porosity of the self-supporting film 1 exceeds 99 vol %, it is difficult to form a self-supporting film state. When the self-supporting film 1 has a porosity of 50 vol % or more and 99 vol % or less, the flexibility is improved while maintaining self-supporting properties.

Since the metal particles 2 are made of silver, the self-supporting film 1 is excellent in heat resistance, thermal conductivity, and electrical conductivity. Since the self-supporting film 1 does not include a Ag foil, it is possible to implement the self-supporting film 1 having a small value of the mass of silver per unit area of 1 mg/cm² or more and 30 mg/cm² or less and maintaining the self-supporting properties.

### 4. EXAMPLES

### <Production of Self-Supporting Film>

A mask provided with a square opening having a length on one side of 1 cm was disposed on the substrate 14, an inert gas was flowed into the chamber 13, the metal 11 was evaporated in the inert gas, and the metal particles 2 were deposited on the substrate 14 to form the self-supporting film precursor 15. Argon (Ar) gas was used as the inert gas. Ag was used as the metal 11. An Si substrate was used as the substrate 14. A temperature of the substrate 14 was room temperature. A deposition time was 115 seconds. Four self-supporting films were produced by changing a pressure of the Ar gas 10 Torr, 30 Torr, 90 Torr, and 270 Torr, to obtain Examples 1 to 4. The self-supporting film according to each of Examples 1 to 4 was recovered as a square self-supporting film having a length on one side of 1 cm by peeling the self-supporting film precursor 15 from the substrate 14 using tweezers and a blower.

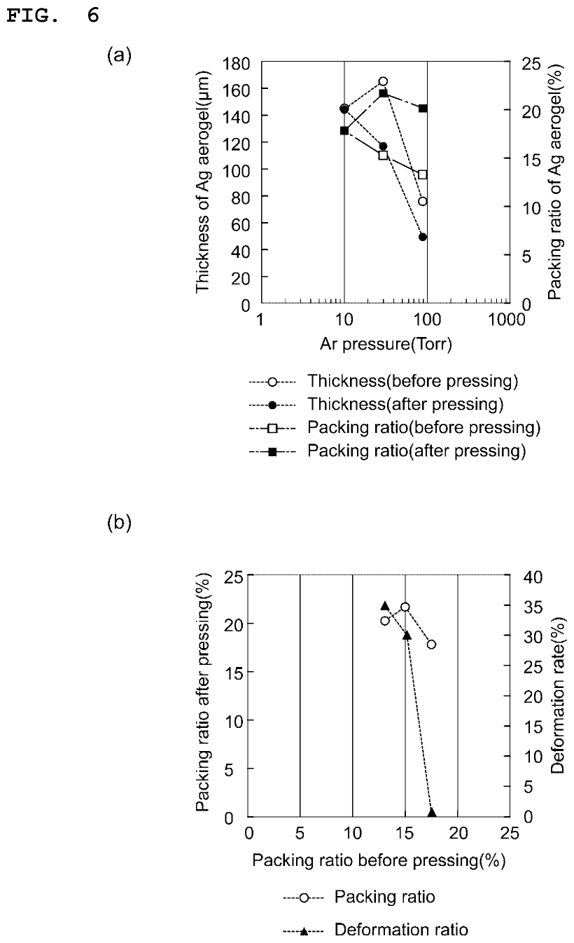

FIG. 5 is a diagram showing a relation between the pressure of the inert gas and characteristics of the self-supporting film during deposition. It is confirmed from the SEM images shown in FIG. 5 that a pillar-shaped structure is obtained in Example 1 (10 Torr), a structure in which particles are deposited is obtained in Example 2 (30 Torr), and a tree-like structure is obtained in Example 3 (90 Torr) and Example 4 (270 Torr), and that Examples 1 to 4 each have a structure with many voids. In Example 1, a mean free path of Ag atoms and Ag nanoparticles during deposition is long, and then coalescence by hitting between Ag atoms, between Ag nanoparticles, and between Ag atoms and Ag nanoparticles does not proceed. Therefore, it is considered that, before the particle diameter of the Ag particles is increased, the Ag particles are deposited on the substrate 14, and sintering of the Ag particles having a large unstable surface with a diameter of about 0.4 μm proceeds to form a pillar-shaped structure. In Example 2, the Ar pressure is higher than that in Example 1. Therefore, the mean free path of Ag atoms and Ag nanoparticles during deposition is short, and then coalescence by hitting proceeds. Therefore, it is considered that in Example 2, the particle diameter of the Ag particles is increased, and stable Ag particles having a diameter of about 1 μm are deposited on the substrate 14 in addition to small Ag particles having a diameter of about 0.3 μm. It is considered that in Examples 3 and 4, the Ag particles that grow even larger as the Ar pressure further increases cannot reach the substrate 14 due to gravity sedimentation, and as a result of only the Ag particles having a medium particle diameter of about 0.6 μm being deposited on the substrate 14, the area loading decreases, and a tree-like structure without a grain boundary in which the Ag particles having a medium particle diameter are partially sintered on the substrate 14 is obtained.

Regarding the particle diameter of the metal particles of the self-supporting film, the self-supporting film was observed at a magnification of 10,000 times using an SEM (S-4800 manufactured by Hitachi High-Technologies Corporation), the metal particles in the SEM image were approximated by an ellipse, a major axis and a minor axis were measured, and a geometric mean of the measured major axis and minor axis was determined and defined as the particle diameter of the metal particles. The particle diameter was measured for 50 metal particles to determine the particle diameter distribution and calculate a number average particle diameter and a volume average particle diameter. The particle diameter distribution was a histogram in which a range of particle diameters of 0.0 μm to 3.0 μm was divided by 0.2 μm, the number of metal particles was counted for each section of the divided particle diameters, a horizontal axis represented the particle diameter, and a vertical axis represented the number of metal particles corresponding to each section of the particle diameters.

A film thickness of the self-supporting film was measured using a laser displacement meter (LK-G30 manufactured by KEYENCE). The film thickness is 165 μm at maximum in Example 2 in which the Ar pressure during deposition is 30 Torr, decreases as the Ar pressure during deposition increases, and is 44 μm in Example 4. The film thickness may be increased by extending the deposition time even under a high Ar pressure condition.

A mass of silver per unit area (shown as “area loading” in FIG. 5) was calculated by measuring a mass of the self-supporting film and dividing the mass by an area of the self-supporting film. The area loading monotonically decreases as the Ar pressure during deposition increases, a maximum value thereof is 26.6 mg/cm² in Example 1, and a minimum value thereof is 5.0 mg/cm² in Example 4.

A packing ratio was calculated by multiplying 100 by a value ([area loading]/([film thickness]×[density of silver]) obtained by dividing the area loading by a value obtained by multiplying the film thickness by a density of silver. The density of silver was 10.5 g/cm³. A porosity was calculated by 100−[packing ratio]. The packing ratio monotonically decreases as the Ar pressure during deposition increases, and the porosity monotonically increases as the Ar pressure during deposition increases. A minimum value of the porosity is 82.4% in Example 1, and a maximum value thereof is 89.2% in Example 4. It is considered that, as the Ar pressure during deposition increases, a proportion of the small particles contained in the Ag particles deposited on the substrate decreases, sintering becomes difficult, and the porosity increases without densification.

### <Film Thickness and Packing Ratio Before and After Pressing>

Using each of the self-supporting films according to Examples 1 to 3 as a sample, the film thickness and the packing ratio of the self-supporting film before and after pressing were measured.

The sample was disposed between two copper blocks (Cu blocks) disposed vertically, and pressed under conditions of 32° C. and 0.8 MPa. The film thickness of the sample was measured before and after pressing, and the packing ratio was calculated. A method for measuring the film thickness and a method for calculating the packing ratio were as described above. The film thickness after pressing was divided by the film thickness before pressing and multiplied by 100 to calculate the film thickness deformation rate.

(a) of FIG. 6 is a graph showing the film thickness and the packing ratio before and after pressing with respect to the Ar pressure during deposition. (b) of FIG. 6 is a graph showing the packing ratio after pressing and the film thickness deformation rate with respect to the packing ratio before pressing. It is confirmed from (a) of FIG. 6 that in Example 1 in which the Ar pressure during deposition is 10 Torr, the change in the film thickness and the packing ratio is small before and after pressing, and in Example 2 in which the Ar pressure is 30 Torr and Example 3 in which the Ar pressure is 90 Torr, the film thickness decreases and the packing ratio increases by pressing. From (b) of FIG. 6, the film thickness deformation rate changes greatly due to the packing ratio before pressing, and the film thickness deformation rate increases greatly as the packing ratio before pressing decreases. In Example 1, the packing ratio before pressing is 17.6% and the film thickness deformation rate is almost 0%, but in Example 3, the packing ratio before pressing is 13.1% and the film thickness deformation rate is as large as about 35%. This indicates that in a self-supporting film having smaller packing ratio, that is, larger porosity, voids are crushed and reduced by pressing, and the film thickness is decreased.

### <Thermal Resistance>

The thermal resistance was measured using each of the self-supporting films according to Examples 1 to 3 as a sample. The thermal resistance was measured by a steady method. The sample was disposed between two Cu blocks disposed vertically, the upper Cu block was heated to 32° C. by a heater and the lower Cu block was cooled by a chiller while being pressed under a condition of 0.8 MPa. A heat flux q was allowed to flow in a plane-perpendicular direction of the sample and allowed to stand still, and the sample was kept in a steady state. Temperatures of the upper and lower Cu blocks in the steady state were measured with a radiant thermometer. A temperature of an end point of the Cu block, that is, a point corresponding to a temperature of an end point of the sample was extrapolated from a temperature profile of the Cu block to obtain a temperature difference ΔT. A thermal resistance Rₜₒₜₐₗ was calculated by dividing the temperature difference ΔT by the heat flux q. The heat flux q used to calculate the thermal resistance Rₜₒₜₐₗ was an average value of heat fluxes of the upper and lower Cu blocks.

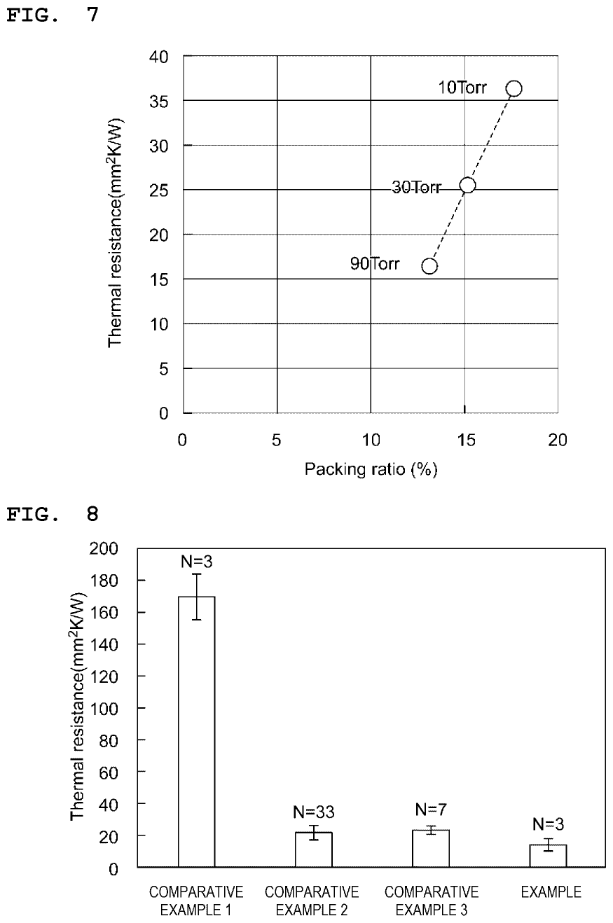

FIG. 7 is a graph showing the thermal resistance of the self-supporting film with respect to the packing ratio before pressing. It can be seen from FIG. 7 that the thermal resistance decreases as the Ar pressure during deposition increases and the packing ratio decreases. It is considered that as the packing ratio decreases and the porosity increases, the self-supporting film is more likely to be deformed in the film thickness direction, and the traceability to the micro roughness on the surface of the Cu block at an interface with the Cu block is improved.

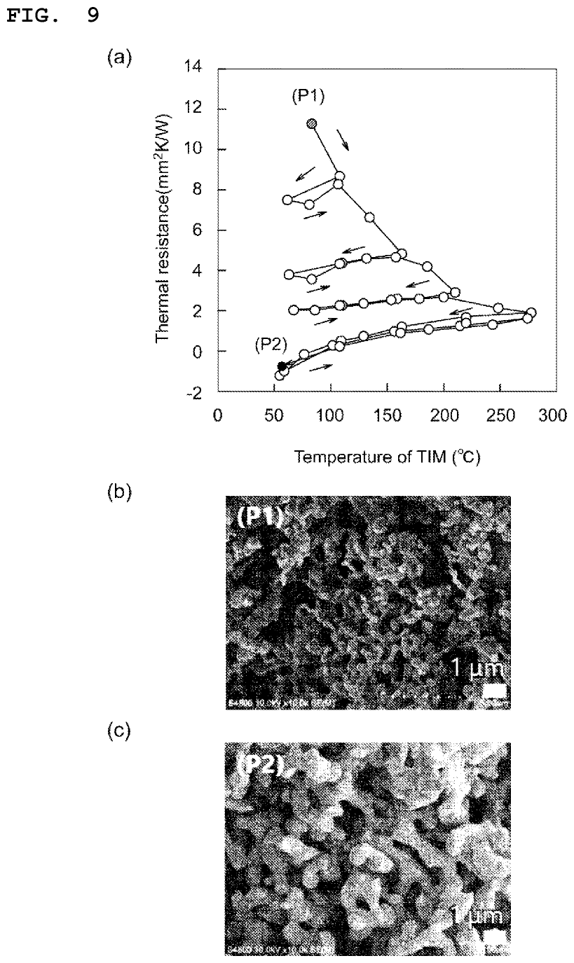

FIG. 8 is a graph showing the thermal resistance in an example and comparative examples. In the Example, the self-supporting film according to Example 3 was disposed between two Cu blocks and pressed under conditions of 32° C. and 0.8 MPa to measure the thermal resistance. In Comparative Example 1, the thermal resistance was measured under the same conditions as in the Example, except that nothing was disposed between two Cu blocks. In Comparative Example 2, an indium sheet having a film thickness of 100 μm was disposed between two Cu blocks, and the thermal resistance was measured under the same conditions as in the Example. In Comparative Example 3, a film in which Ag layers having a film thickness of 15 μm to 61 μm were formed under the same conditions as in Example 3 on both surfaces of an Ag foil having a film thickness of 50 μm was disposed between two Cu blocks, and the thermal resistance was measured under the same conditions as in the Example. In FIG. 8, N represents the number of measurements on the thermal resistance, the graph shows an average value of measured values, and an error bar shows a standard deviation. It is confirmed from FIG. 8 that the thermal resistance in the Example is 16 mm²K/W, which is about 1/10 of that in Comparative Example 1. Further, it is confirmed that a thermal resistance value in the Example lower than that in Comparative Examples 2 and 3 is obtained. It is considered that this is because with respect to an indium sheet or a film including an Ag foil, the self-supporting film according to Example 3 is flexible and easily deformed in the film thickness direction, and the traceability to the micro roughness on the surface of the Cu block is improved at the interface with the Cu block.

Next, results of testing the change in thermal resistance with respect to a heating temperature are shown in (a) to (c) of FIG. 9. (a) of FIG. 9 is a graph in which a horizontal axis represents the heating temperature and a vertical axis represents the thermal resistance. The self-supporting film according to Example 3 was disposed between two Cu blocks, the thermal resistance was measured under a pressure of 0.8 MPa under heating in a temperature cycle in which heating and cooling were repeated. In the temperature cycle, a temperature at the start of measurement indicated by P1 was 82° C., and a cycle of 82° C.→108° C.→50° C.→162° C.→50° C.→211° C.→50° C.→279° C. was performed, as shown in (a) of FIG. 9. After the temperature cycle test, the thermal resistance was measured twice in a cycle of 50° C.→280° C.→50° C., and the measurement was terminated at 50° C. indicated by P2.

The thermal resistance is 11.3 mm²K/W at 82.1° C., 8.7 mm²K/W at 108° C., 4.8 mm²K/W at 162° C., 2.9 mm²K/W at 211° C., and 1.8 mm²K/W at 279° C., and it is confirmed that the thermal resistance decreases as the temperature increases. It is also confirmed that once the thermal resistance decreases at a high temperature, the low thermal resistance is maintained even when the temperature of the self-supporting film is returned to 50° C. In particular, when the temperature is returned to 50° C. after heating to 279° C. (P2), the thermal resistance decreases to a measurement lower limit or less. In the graph, the calculated values are plotted as they are, but the values do not take a negative value, and are approximately 0 mm²K/W. It is considered that this is because the self-supporting film becomes flexible by the heating, the interface traceability with the Cu block is improved, the contact thermal resistance is reduced, the sintering between Ag particles proceeds to be bulky, the Cu blocks are thermally bonded, and the thermal resistance is reduced.

(b) of FIG. 9 is an SEM image showing a cross section of the self-supporting film at a point indicated by P1 in (a) of FIG. 9 (at start of temperature cycle), and (c) of FIG. 9 is an SEM image showing a cross section of the self-supporting film at a point indicated by P2 in (a) of FIG. 9 (after temperature cycle). It can be confirmed that by the temperature cycle sintering between the Ag particles proceeds, the diameter of the particles increases, and the tree-like structure of silver of several tens to several hundreds of nanometers is enlarged to several micrometers.

### <Heat Resistance>

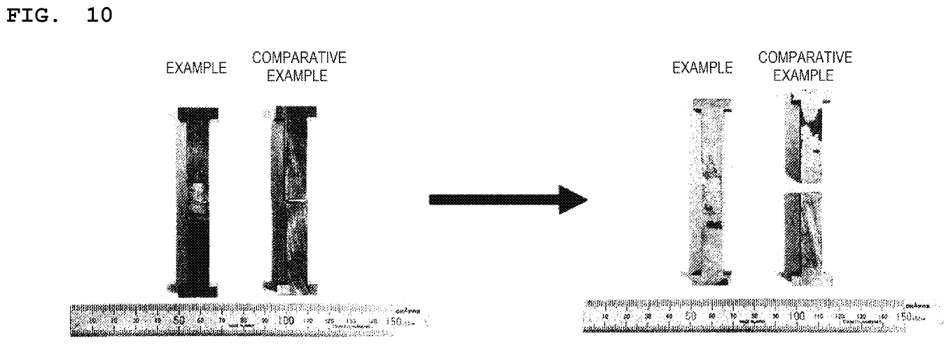

Results of testing the heat resistance of the self-supporting film are shown in FIG. 10. The self-supporting film according to Example 3 was disposed between two Cu blocks and pressed under conditions of 300° C. and 100 MPa to prepare a sample. As a comparative example, a sample was prepared by disposing an indium sheet having a film thickness of 100 μm between two Cu blocks and pressing under conditions of 150° C. and 100 MPa. Each of the samples according to the example and the comparative example was suspended inside a heating device and heated from 25° C. to 900° C. in an air atmosphere. A heating rate was 5° C./min.

As shown in FIG. 10, in the comparative example, the lower Cu block was separated and dropped at 536° C. On the other hand, in the example, a fixed state of the upper and lower Cu blocks was maintained to 900° C., and the fixed state was maintained even after cooling. It is considered that, since the self-supporting film has a nanostructure containing Ag particles having a clean surface and a volume average particle diameter of 0.1 μm or more and 3 μm or less, the Cu blocks are welded by pressing at 300° C. and 100 MPa, and high interface stability is obtained. Since the self-supporting film does not contain an organic polymer which is thermally unstable, it is considered that the thermal stability of a bonding portion is excellent and high heat resistance of a bonding interface is obtained.

### <Electrical Resistance>

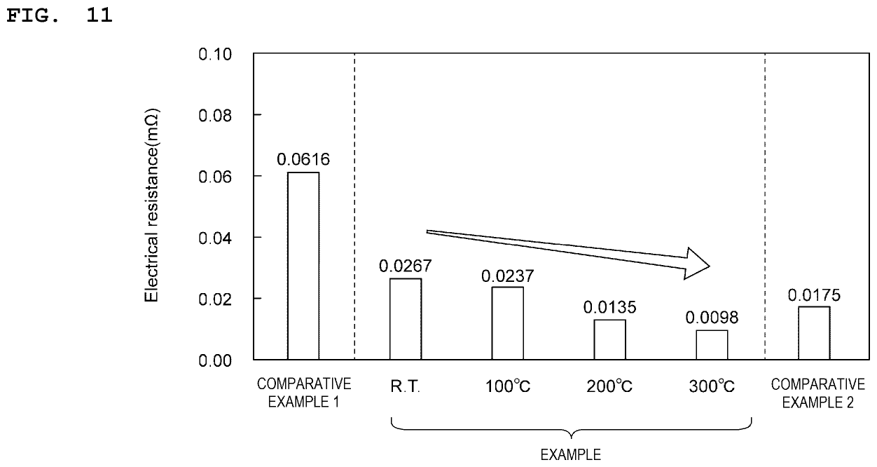

Results of measuring the electrical resistance are shown in FIG. 11. The self-supporting film according to Example 3 was used as an Example, and the electrical resistance in the plane-perpendicular direction of the self-supporting film was measured by a four-terminal method. Strip-shaped copper plates each having a width of 7 mm and a thickness of 0.2 mm were disposed orthogonal to each other, and the self-supporting film was disposed between the copper plates. The self-supporting film was sandwiched between the copper plates, and the electrical resistance was measured at room temperature in a pressed state of 0.8 MPa. Further, the self-supporting film was sandwiched between the copper plates, and the self-supporting film was pressed and sintered at 100 MPa in a state of heating at 100° C., heating at 200° C., and heating at 300° C., and then the electrical resistance was measured at room temperature in a pressed state of 0.8 MPa. In the measurement on the electrical resistance, a voltage was applied between the copper plates using a multimeter, and a value of a current flowing between the copper plates was measured. The used multimeter was a digital multimeter (KEITHLEY 2400 manufactured by KEITHLEY). The electrical resistance value was calculated based on a slope of a current-voltage line according to the Ohm's law.

As Comparative Example 1, two copper plates were disposed orthogonal to each other and brought into contact with each other, and the electrical resistance was measured while pressing at 0.8 MPa at room temperature. As Comparative Example 2, two copper plates were disposed orthogonal to each other, an Ag paste containing an organic dispersant and a metal filler was disposed between the copper plates and pressed at 100 MPa in a state of heating at 150° C., and then the electrical resistance was measured while pressing at 0.8 MPa at room temperature.

FIG. 11 shows the electrical resistance values according to Comparative Examples 1 and 2 and Examples when the temperature conditions are room temperature, 100° C., 200° C., and 300° C. It is confirmed that the electrical resistance is lower in the Examples in which the self-supporting film is sandwiched than in Comparative Example 1 in which the copper plates are in direct contact with each other. This is because the flexible self-supporting film is deformed tracing an interface with the copper plate, and a contact area between the self-supporting film and the copper plates is increased. It is understood that when the Examples of different temperature conditions are compared with one another, as the temperature is higher, the electrical resistance is lower. It is considered that this is because the self-supporting film becomes flexible as the temperature becomes higher, the interface traceability to the copper plate is improved, the contact electrical resistance is reduced, the sintering of the Ag particles proceeds to become bulky, the copper plates are electrically bonded, and the electrical resistance is reduced. The Examples in which the temperature conditions are 200° C. and 300° C. exhibit lower electrical resistance than Comparative Example 2 in which the Ag paste is used. While the Ag paste contains an organic polymer, the self-supporting films according to the Examples do not contain an organic polymer, and therefore, the self-supporting film is compressed by pressing, the number of contact points where the Ag particles are in direct contact with one another is increased, and an electrically conductive path by the Ag particles is formed. Although not shown, in the Examples in which the temperature conditions are 200° C. and 300° C., a space between the copper plates is mechanically fixed by the self-supporting film.

### <Mechanical Strength>

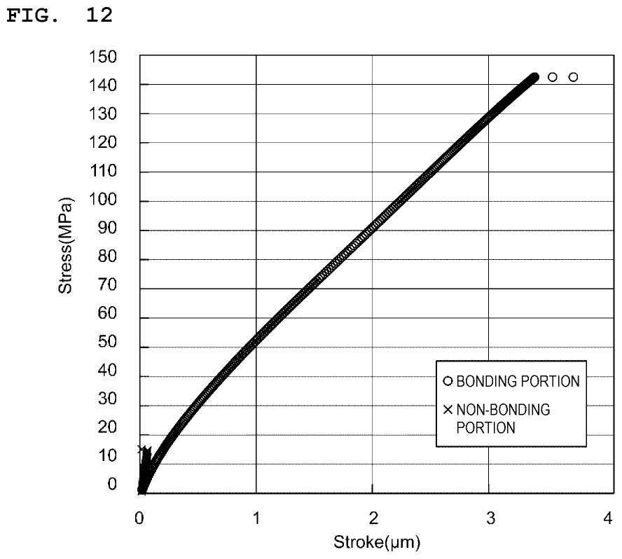

Results of a tensile test for evaluating the mechanical strength of the self-supporting film are shown in FIG. 12. The self-supporting film according to Example 3 was disposed between two Cu blocks and pressed under conditions of 300° C. and 100 MPa to 1,000 MPa to prepare a sample. In the tensile test, a universal testing machine “AUTOGRAPH AG-100 kN” by Shimadzu Corporation was used. The sample was disposed in the universal testing machine and subjected to the tensile test under a condition of a tensile stress of 140 MPa.

FIG. 12 shows, with a stroke (elongation) (μm) calculated based on a strain value and a gauge length as a horizontal axis and the tensile stress (MPa) as a vertical axis, the tensile stress with respect to the stroke of a bonding portion (bonding portion) by the self-supporting film and the Cu blocks (non-bonding portion). In FIG. 12, the bonding portion is plotted with o, and the non-bonding portion is plotted with x. It is confirmed from FIG. 12 that the bonding portion does not break up to a tensile stress of 140 MPa, and the bonding portion is displaced while absorbing the tensile stress and exhibits high mechanical strength.

The present invention is not limited to the above embodiments and examples, and may be appropriately modified within the scope of the gist of the present invention.

The self-supporting film 1 and a carrier substrate may constitute a stacked sheet. In the stacked sheet, the self-supporting film 1 may be held in a pattern shape on the carrier substrate. The carrier substrate is for temporarily holding the self-supporting film 1, and is formed of a material from which the self-supporting film 1 may be peeled off. Examples of the material of the carrier substrate include a temporary adhesive film having low adhesiveness and a heat release tape. The carrier substrate may be, for example, a long flexible tape. The stacked sheet is effective for transportation and storage because the self-supporting film 1 is held by the carrier substrate, and is excellent in handleability of the self-supporting film 1 because the self-supporting film 1 can be easily peeled from the carrier substrate.

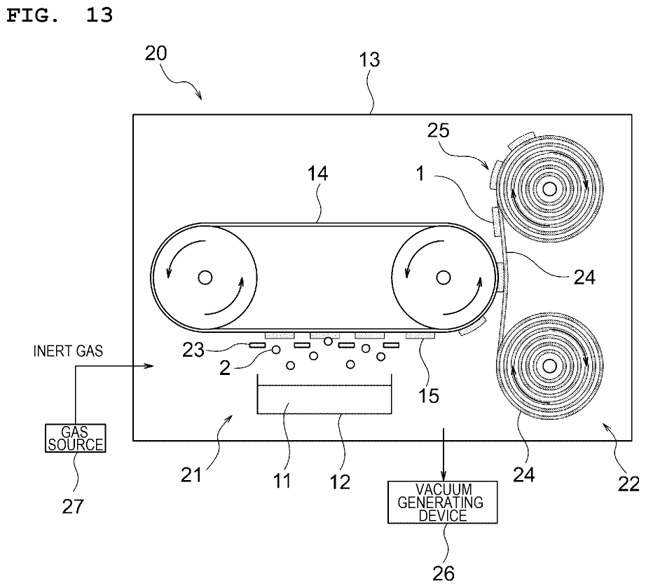

FIG. 13 is a schematic diagram schematically illustrating an example of a stacked sheet manufacturing apparatus. A stacked sheet manufacturing apparatus 20 includes the substrate 14 having an endless belt shape that may be orbited, a self-supporting film precursor forming unit 21 that deposits the metal particles 2 generated by evaporating the metal 11 on the substrate 14 to form the self-supporting film precursor 15 having a porous structure consisting of the aggregates 3 of the metal particles 2 and the voids 4 on the substrate 14, a self-supporting film precursor peeling unit 22 that peels off the self-supporting film precursor 15 from the substrate 14 and transfers the self-supporting film precursor 15 to a movable carrier substrate 24, and the chamber 13 that accommodates the substrate 14, the self-supporting film precursor forming unit 21, and the self-supporting film precursor peeling unit 22.

The self-supporting film precursor forming unit 21 includes the metal 11 as a vapor deposition source, the boat 12 that accommodates the metal 11, and a mask 23 provided between the metal 11 and the substrate 14. A vacuum generating device 26 and an inert gas source 27 are connected to the chamber 13.

The stacked sheet manufacturing apparatus 20 evaporates the metal 11 in an inert gas of 10 Torr or more and 300 Torr or less, generates the metal particles 2 made of the metal 11, deposits the metal particles 2 on the orbiting substrate 14 to form the self-supporting film precursor 15 having a porous structure (aerogel structure), and transfers the self-supporting film precursor 15 from the substrate 14 to the carrier substrate 24, thereby manufacturing a stacked sheet 25 including the self-supporting film 1 and the carrier substrate 24. The self-supporting film 1 can be produced by peeling the self-supporting film precursor 15 from the substrate 14. That is, the stacked sheet manufacturing apparatus 20 can be used as a self-supporting film manufacturing apparatus for manufacturing the self-supporting film 1. In the stacked sheet manufacturing apparatus 20 illustrated in FIG. 13, the stacked sheet 25 in which the self-supporting film 1 is held in a pattern shape on the carrier substrate 24 is manufactured by using the mask 23.

Examples of the material constituting the metal particles 2 include, in addition to silver, metals such as gold, copper, aluminum, zinc, indium, and tin, and alloys such as silver-copper alloy, aluminum-silicon alloy, tin-zinc alloy, tin-silver alloy, and tin-silver-copper alloy.

In the example illustrated in FIGS. 3 and 13, the boat 12 has both a function as a crucible that accommodates the metal 11 as a vapor deposition source and a function as a heater that heats and evaporates the metal 11, but is not limited thereto. For example, the boat 12 may be a crucible that accommodates the metal 11 as a vapor deposition source, and may be configured to evaporate the metal 11 by heating the boat 12 by a separately provided heater. The metal 11 may be continuously supplied to the boat 12.

### REFERENCE SIGN LIST

1 self-supporting film
2 metal particle
3 aggregate
4 void

1. A self-supporting film comprising: a porous structure consisting of aggregates of metal particles and voids.

2. The self-supporting film according to claim 1, wherein a volume average particle diameter of the metal particles is 0.1 μm or more and 3 μm or less.

3. The self-supporting film according to claim 1, wherein a porosity is 50 vol % or more and 99 vol % or less.

4. The self-supporting film according to claim 1, wherein the metal particles are made of silver.

5. The self-supporting film according to claim 4, wherein a mass of the silver per unit area is 1 mg/cm2 or more and 50 mg/cm2 or less.

6. The self-supporting film according to claim 1, wherein the self-supporting film does not include an organic polymer.

7. The self-supporting film according to claim 1, wherein the self-supporting film does not include a metal foil.

8. The self-supporting film according to claim 1, which is a self-supporting film for an interfacial bonding material.

9. The self-supporting film according to claim 1, which is a self-supporting film for a thermal interface material.

10. A stacked sheet comprising:
the self-supporting film according to claim 1; and
a carrier substrate.

11. The stacked sheet according to claim 10, wherein the self-supporting film is held in a pattern shape on the carrier substrate.

12. A method for producing a self-supporting film, comprising:
evaporating a metal in an inert gas of 10 Torr or more and 300 Torr or less to generate metal particles made of the metal;
depositing the metal particles on a substrate to form, on the substrate, a self-supporting film precursor having a porous structure consisting of aggregates of the metal particles and voids; and
peeling the self-supporting film precursor from the substrate.
